(19) United States
(12) Patent Application Publication
(10) Pub. No.: US 2004/0123195 A1
(43) Pub. Date: Jun. 24, 2004

(54) Systems and methods for testing tri-state bus drivers

(76) Inventors: John G. Rohrbaugh, Ft Collins, CO (US); Jeff Rearick, Ft Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/327,542

(22) Filed: Dec. 20, 2002

(51) Int. Cl. G01R 31/28

(52) U.S. Cl. 714/724

(57) ABSTRACT

Systems and methods are provided to test tri-state bus drivers An embodiment of a system includes a tri-state bus to be tested, and at least one tri-state driver connected to the tri-state bus. Either a pull-up driver test circuitry or a pull-down driver test circuitry is connected to the tri-state bus to be tested, and enable the testing of the tri-state driver. An embodiment of a method for testing tri-state bus drivers comprises: selecting the tri-state bus to be tested and performing a tri-state test on the tri-state bus to be tested; switching off enable signals for all drivers on the tri-state bus, forcing the tri-state bus to a first value; setting all driver data inputs to a second value different than the first value, and determining if the first value remains on the tri-state bus.

### BACKGROUND OF THE INVENTION

1. Field of the Invention

The present invention generally relates to testing of tri-state logic and, more particularly, to systems and methods for evaluating tri-state bus drivers and associated circuitry.

2. Discussion of the Related Art

Integrated circuits (ICs) are electrical circuits composed of transistors, resistors, capacitors, and other components on a single semiconductor “chip” in which the components are interconnected to perform a variety of functions. Typical examples of ICs include, for example, microprocessors, programmable logic devices (PLDs), electrically erasable programmable memory devices (EEPROMs), random access memory devices (RAMs), operational amplifiers and voltage regulators.

A circuit designer typically designs an IC by creating a circuit schematic indicating the electrical components and their interconnections. Often, designs are simulated by a computer to verify functionality and to ensure that performance goals are satisfied. While these designs can be simulated to verify functionality and performance goals, there are various shortcomings when completing actual testing. For instance, it is known that it is difficult to perform digital tests on circuitry that can behave non-digitally. Examples of circuitry that can behave non-digitally include tri-state devices, such as tri-state drivers.

In order to actually test an enable line of a tri-state driver, a value should be defined on the tri-state bus when all the drivers are off. This is because the normal default off values for a tri-state driver on the tri-state bus (i.e. an internal node) cannot be reliably propagated to an external chip pin. If there is no default value on the tri-state bus, the tri-state driver enable lines become untestable and a test may not discover bad parts. However, adding circuitry to define a value can slow the overall performance of the original circuit.

Additional circuitry to define a value can include, but is not limited to, putting a bus-keeper on the tri-state bus. The tri-state bus-keeper typically requires a two-step test, with a first step to initialize and the second step to test. This two-step test can be complicated. Moreover, the technique of putting a bus keeper on the tri-state bus may compromise the circuit performance. Thus, tri-state circuitry is not currently considered fully testable, and, therefore, the use of tri-state circuitry may be reduced or even avoided.

### SUMMARY OF THE INVENTION

Systems and methods for evaluating the circuitry of tri-state bus drivers are provided. Briefly described, in architecture, an embodiment of a system includes a tri-state bus to be tested, and at least one tri-state bus driver connected to the tri-state bus. Either pull-up driver test circuitry or pull-down driver test circuitry is connected to the tri-state bus to be tested, enabling the testing of the tri-state driver.

An embodiment of a method for testing tri-state bus drivers of a tri-state bus in an integrated circuit can be summarized by the following steps: (1) selecting a tri-state bus to be tested, (2) switching off enable signals for all drivers on the tri-state bus, (3) forcing the tri-state bus to a first value, (4) setting all driver data inputs to a second value different than the first value, and (5) determining if the first value remains on the tri-state bus.

### DESCRIPTION OF THE DRAWINGS

The accompanying drawings incorporated in and forming a part of the specification illustrate several aspects of the present invention, and together with the description serve to explain the principles of the invention. In the drawings:

FIG. 1 is a schematic diagram illustrating one possible hardware implementation of a driver analyzer apparatus utilized to test tri-state bus drivers on a chip.

FIG. 2 is a block diagram illustrating an alternative embodiment of the driver analyzer of FIG. 1, implemented in a computer-readable medium in a computer system.

FIG. 3 is a flow chart depicting one possible implementation of a driver analyzer used in conjunction with driver analyzer circuitry to test tri-state bus drivers as shown in FIGS. 1 and 2.

FIG. 4 is a flow chart illustrating one possible implementation of a driver pull-up test utilized in a driver analyzer as shown in FIGS. 1, 2, and 3.

FIG. 5 is a flow chart illustrating one possible implementation of a driver pull-down test utilized in the driver analyzer of the present invention as shown in FIGS. 1, 2, and 3.

### DETAILED DESCRIPTION

Having summarized various aspects of the present invention, the invention will now be described in detail with reference to the drawings. While the invention will be described in connection with these drawings, there is no intent to limit it to the embodiment or embodiments disclosed therein. On the contrary, the intent is to cover all alternatives, modifications and equivalents included within the spirit and scope of the invention as protected by the appended claims.

In order to test the enable line of a tri-state bus driver for a stuck-on fault (i.e. driver is always driving and can never be tri-stated), a value must be defined on the tri-state bus when all tri-state bus drivers are off. This is because the normal default value (i.e. the value present on the tri-state bus when all of its tri-state drivers are disabled) of a tri-state bus on an internal node (i.e. the tri-state bus) cannot be reliably propagated to an external pin of the chip.

Embodiments of the driver analyzer describe a test circuit, which enables testing of the enable line of a tri-state bus driver with reduced impact to circuit performance. In some driver analyzers, pull-up and pull-down circuitry are used to define the initial value on the tri-state bus. In one such embodiment, field effect transistors (FET) are used for the pull-up and pull-down circuitry. The pull-up and pull-down circuitry are controlled by test signals. During normal operation, the driver analyzer is affected by the additional load of a trace of a wire to an open FET. This trace of a wire to an open FET has a very minor effect on the circuit, as compared to the typical capacitance of a tri-state bus and all its drivers. During a test mode, either the pull-up FET or the pull-down FET can be enabled to put a default value on the tri-state bus.

In alternative embodiments, a scanable latch can be added to the driver analyzer circuitry. This scanable latch can then be enabled during the test. This should make the task of observing the test results simpler. The scanable latch can be used to capture output from the tri-state bus and could be connected to the tri-state bus.

In other alternative embodiments, two scanable registers can be added to driver analyzer circuitry, such that their outputs control the pull-up and pull-down tri-state bus testing FETs. In such an embodiment, a default value for each FET can be controlled independently. Typically, these registers would be powered-up such that the FETs would be off during normal operation of the tri-state bus circuit.

Embodiments of the driver analyzer typically make passes through the driver circuitry on a tri-state bus in an attempt to identify problem tri-state driver circuits. In the first pass, the driver analyzer typically tests all the tri-state drivers on a selected bus at once using a pull-up test. If the pull-up test fails, then there is no need for further testing of the drivers on the tri-state bus, as at least one of them is a defective circuit.

However, if all the drivers on the tri-state bus pass the pull-up test, the driver analyzer may, such as in response to a user request, test all the tri-state drivers on the selected bus at once using a pass a pull-down test. If the user does request that the pull-down test be run and the pull-down test fails, then it may be concluded that at least one of the drivers of the tri-state bus is a defective circuit. However, if the user does request that both the pull-up and the pull-down test be run and all the tri-state drivers on the tri-state bus pass both the pull-up and pull-down tests, then it may be concluded that all the drivers for the tri-state bus under test are valid circuits.

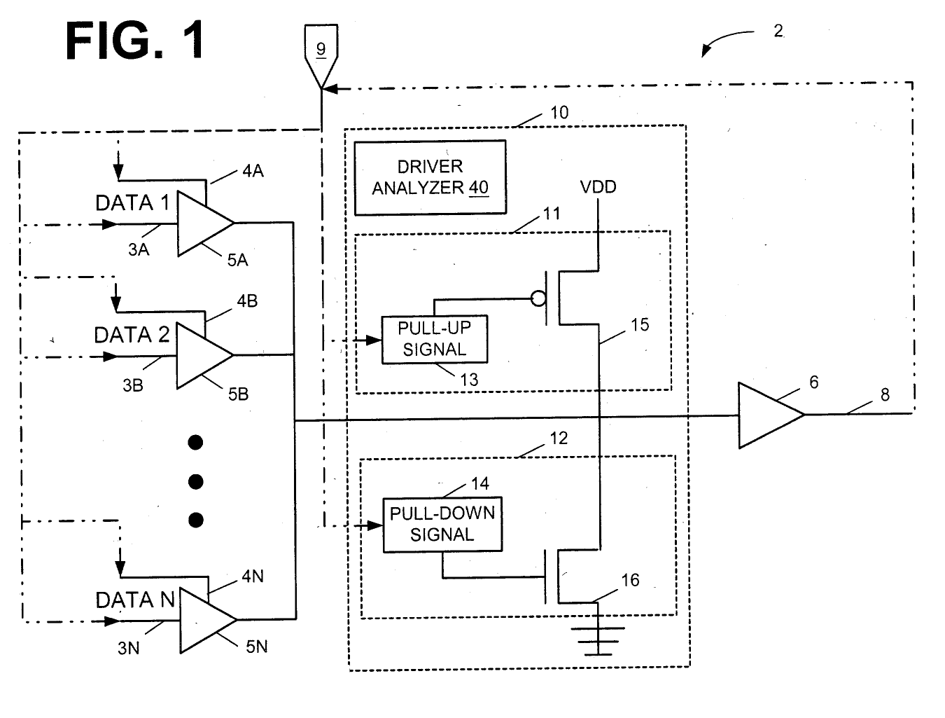

Illustrated in FIG. 1 is a schematic diagram illustrating an example of one possible hardware implementation of a system (driver analyzer circuitry) 10 on tri-state bus circuitry 2. Briefly, the driver analyzer circuitry 10 is comprised of pull-up circuitry 11 and pull-down test circuitry 12, that are each connected to tri-state bus 6 and enable testing of the tri-state bus drivers 5 (A-N). Driver analyzer circuitry 10 also can optionally include driver analyzer (not shown) for controlling the driver analyzer circuitry, 10. Although FIG. 1 shows a buffer 7 between tri-state bus 6 and wire 8, which is connected to a port 9, it should be understood that a variety of circuitry may be present between the tri-state bus 6 and the port 9, given that a tri-state bus is an internal node (i.e. not a port) of an integrated circuit.

To implement the pull-up test, a pull-up signal 13 is applied to the FET 15, which connects VDD to the tri-state bus 6. Upon applying the pull-up signal 13 to the pull-up FET 15, the tri-state drivers 5 (A-N) on tri-state bus 6 can be tested. The testing is started by turning off all drivers 5(A-N) using driver enable lines 4(A-N) on the tri-state bus 6 under test. Then, the pull-up test circuit 11 is enabled to pull-up the tri-state bus 6. The pull-up signal 13 connects the pull-up FET 15 to VDD. Upon connecting the pull-up FET 15 to VDD, a high signal is then connected to the tri-state bus 6, thereby pulling the tri-state bus 6 high. In some embodiments, the high signal is a weak signal that can be overridden by one of the tri-state drivers 5 (A-N). However, it should be understood that the high signal need only be weak enough for the signal to be overridden by one of the tri-state drivers 5 (A-N). The data input lines 3(A-N) are then driven low and the tri-state bus 6 is tested for a high condition. If the tri-state bus 6 remains high, then the tri-state bus drivers 5 (A-N) have passed the test.

A similar procedure is utilized in order to perform a pull-down test on the tri-state bus 6. The testing is started by turning off all tri-state drivers 5 (A-N) using driver enable lines 4(A-N) on the tri-state bus 6 under test. The pull-down test circuit 12 is enabled to pull-up the tri-state bus 6. The pull-down signal 14 connects the pull-down FET 16 to ground. Upon connecting the pull-down FET 16 to ground, a low signal is then connected to the tri-state bus 6, thereby pulling the tri-state bus 6 low. In some embodiments, the low signal is a weak signal that can be overridden by one of the tri-state drivers 5 (A-N). However, it should be understood that the high signal need only be weak enough for the signal to be overridden by one of the tri-state drivers 5 (A-N). The data input lines 3(A-N) are then driven high and the tri-state bus 6 is tested for a low condition. If the tri-state bus 6 remains low, then the tri-state bus drivers 5 (A-N) have passed the test. If the tri-state bus drivers 5 (A-N) pass one or both of the pull-up and pull-down tests, then one can assume that the tri-state bus drivers 5 (A-N) of the tri-state bus 6 under test do not have their enables lines stuck on.

In some embodiments, the driver analyzer circuitry 10, pull-up circuitry 11 and pull-down circuitry 12, tri-state bus 6 and tri-state bus drivers 5 (A-N) can be controlled and observed by a port 9. However, it should be understood that multiple ports may be used for control and observe purposes. The port 9 enables a driver analyzer 40 to input control and data signals from a computer system outside of tri-state bus circuitry 2. Data signals can be input to tri-state bus drivers 5 (A-N) and control signals can be used to provide control of the tri-state bus drivers 5 (A-N), pull-up signal 13 and pull-down signal 14. These data and control signals will determine the data which is placed onto the tri-state bus 6. The port 9 also enables the driver analyzer 40 receive data signals from the buffered bus output 8.

In an alternative embodiment, the driver analyzer circuitry 10 and/or an associated driver analyzer (not shown) can be implemented in hardware on the chip (not shown) to be tested. In such a hardware embodiment, the driver analyzer circuitry 10 and/or driver analyzer can be implemented with any one or a combination of the following technologies, which are each well known in the art: a discrete logic circuit(s) having logic gates for implementing logic functions upon data signals, an application specific integrated circuit(s) (ASIC) having appropriate combinational logic gates, a programmable gate array(s) (PGA), a field programmable gate array(s) (FPGA), etc.

In some embodiments, a scanable latch (not shown) can be added to the driver analyzer circuitry. This scanable latch can then be enabled during the test. The scanable latch can be used for output from the tri-state bus and would be connected to the tri-state bus.

In some embodiments, two scannable registers (not shown) can be added to the driver analyzer circuit such that their outputs control the pull-up and pull-down tri-state bus testing FETs. In such an embodiment, a default value for each FET can be controlled independently.

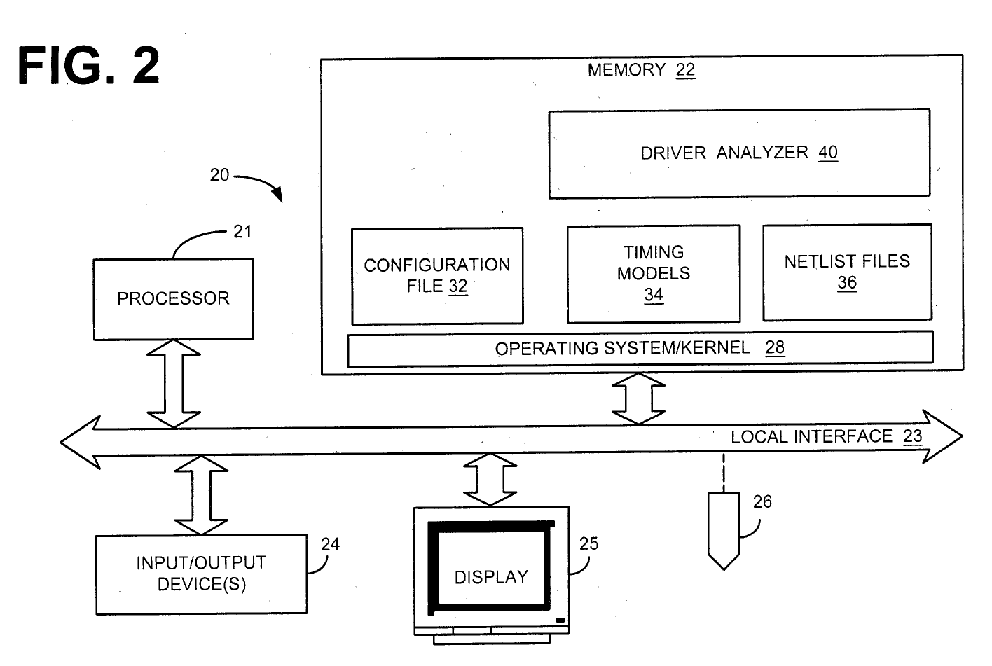

FIG. 2 is a block diagram illustrating an example of an embodiment of a driver analyzer 40 implemented by a computer-readable medium, such as, for example, a memory in a general-purpose computer system 20. Generally, in terms of hardware architecture, as shown in FIG. 2, the computer system 20 includes a processor 21, memory 22, and one or more input devices and/or output (I/O) devices (or peripherals) that are communicatively coupled via a local interface 23. The local interface 23 can be, for example but not limited to, one or more buses or other wired or wireless connections, as is known in the art. The local interface 23 may have additional elements, which are omitted for simplicity, such as controllers, buffers (caches), drivers, repeaters, and receivers, to enable communications. Further, the local interface 23 may include address, control, and/or data connections to enable appropriate communications among the aforementioned components.

The processor 21 is a hardware device for executing software that can be stored in memory 22. The processor 21 can be virtually any custom made or commercially available processor, a central processing unit (CPU) or an auxiliary processor among several processors associated with the computer 20, and a semiconductor based microprocessor (in the form of a microchip) or a macroprocessor.

The memory 22 can include any one or combination of volatile memory elements (e.g., random access memory (RAM, such as DRAM, SRAM, etc.)) and nonvolatile memory elements (e.g., ROM, hard drive, tape, CDROM, etc.). Moreover, the memory 22 may incorporate electronic, magnetic, optical, and/or other types of storage media. Note that the memory 22 can have a distributed architecture, where various components are situated remote from one another, but can be accessed by the processor 21.

The software in memory 22 may include one or more separate programs, each of which comprises an ordered listing of executable instructions for implementing logical functions. In the example of FIG. 2, the software in the memory 12 includes an operating system 28, the driver analyzer 40, the configuration file 32, timing models 34, and the netlist file 36. The configuration file(s) 32 contains information that informs the driver analyzer 40 how to perform its analysis, and various numbers of configuration file(s) 32 may be used. The timing models file 34 contains information that informs the driver analyzer 40 of the various timing sequences of each particular tri-state bus driver 5 (A-N) components. The netlist file 36, as is well known, defines the various integrated circuit components, and their inter-relations.

The operating system 28 essentially controls the execution of other computer programs, such as the driver analyzer circuitry 10, and provides scheduling, input-output control, file and data management, memory management, and communication control and related services.

The driver analyzer 40 may be a source program, executable program (object code), script, or any other entity comprising a set of instructions to be performed. When a source program, then the program is usually translated via a compiler, assembler, interpreter, or the like, which may or may not be included within the memory 22, so as to operate properly in connection with the O/S 28. Furthermore, the driver analyzer 40 can be written as (a) an object oriented programming language, which has classes of data and methods, or (b) a procedure programming language, which has routines, subroutines, and/or functions, for example but not limited to, C, C++, Pascal, BASIC, FORTRAN, COBOL, Perl, Java, and Ada.

The I/O devices 24 may include input devices, for example but not limited to, a keyboard, mouse, scanner, microphone, etc. Furthermore, the I/O devices 14 may also include output devices, for example but not limited to, a printer, display 25, etc. Finally, the I/O devices 24 may further include devices that communicate both inputs and outputs, for instance but not limited to, a modulator/demodulator (modem; for accessing another device, system, or network), a radio frequency (RF) or other transceiver, a telephonic interface, a bridge, a router, etc. The computer system 20 includes chip interface 26 for use in accessing a chip. This chip interface 26 accesses pull-up circuitry 11, pull-down circuitry 12, tri-state bus 6 and tri-state bus drivers 5 (A-N), as shown in FIG. 1, using the port 9 (FIG. 1) in order to test operation on the tri-state bus drivers 5 (A-N).

If the computer 20 is a PC, workstation, or the like, the software in the memory 22 may further include a basic input output system (BIOS) (omitted for simplicity). The BIOS is a set of essential software routines that initialize and test hardware at startup, start the O/S 28, and support the transfer of data among the hardware devices. The BIOS is stored in ROM so that the BIOS can be executed when the computer 20 is activated.

When the computer 20 is in operation, the processor 11 is configured to execute software stored within the memory 22, to communicate data to and from the memory 22, and to generally control operations of the computer 20 pursuant to the software. The driver analyzer circuitry 10 of the present invention and the O/S 28 are read, in whole or in part, by the processor 21, perhaps buffered within the processor 21, and then executed.

When the driver analyzer 40 is implemented in software, as is shown in FIG. 2, it should be noted that can be stored on virtually any computer-readable medium for use by or in connection with any computer-related system or method. In the context of this document, a computer-readable medium is an electronic, magnetic, optical, or other physical device or means that can contain or store a computer program for use by or in connection with a computer related system or method. The driver analyzer 40 can be embodied in any computer-readable medium for use by or in connection with an instruction execution system, apparatus, or device, such as a computer-based system, processor-containing system, or other system that can fetch the instructions from the instruction execution system, apparatus, or device and execute the instructions.

In the context of this document, a “computer-readable medium” can be any means that can store, communicate, propagate, or transport the program for use by or in connection with the instruction execution system, apparatus, or device. The computer readable medium can be, for example but not limited to, an electronic, magnetic, optical, electromagnetic, infrared, or semiconductor system, apparatus, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM, EEPROM, or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory.

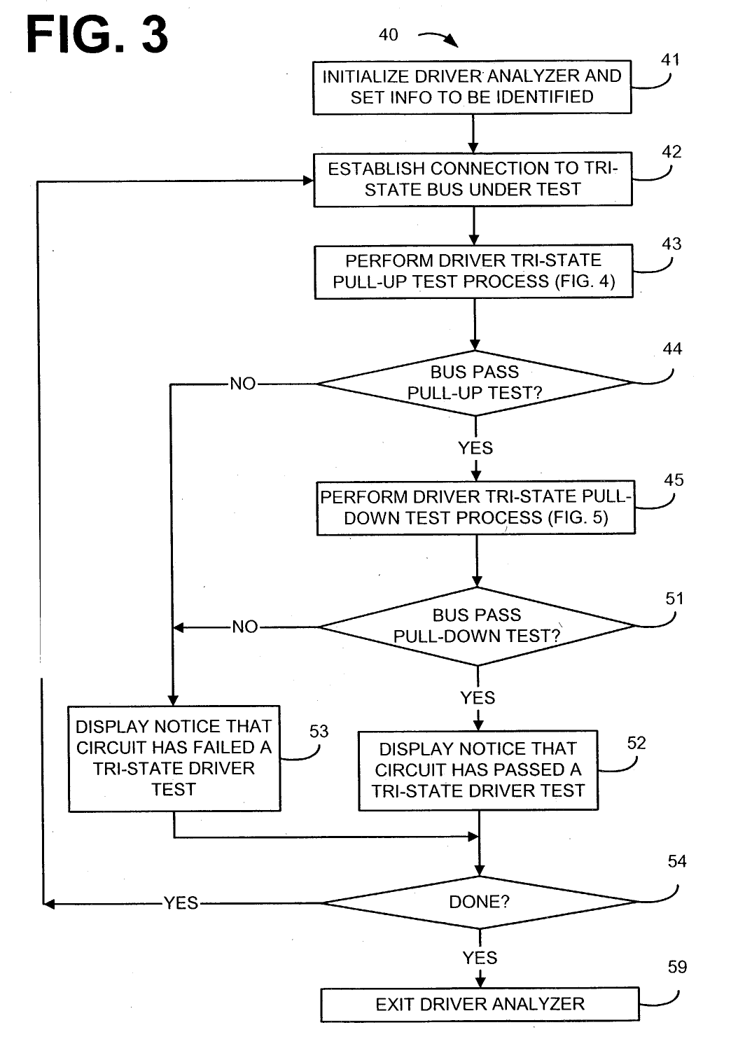

Illustrated in FIG. 3, is a flow chart depicting one possible implementation of the driver analyzer 40 used in conjunction with the driver analyzer circuitry 10 to test tri-state bus drivers 5 (A-N), as shown in FIGS. 1 and 2. The driver analyzer 40 can be performed in an on-chip or off-chip (FIG. 2) manner. Off-chip operation of the driver analyzer 40 can be performed using the port 9 (FIG. 1) to connect chip interface 26 (FIG. 2). In on-chip operation of the driver analyzer 40, the driver analyzer 40 would be located on chip and include connections to the same elements connected to the port 9 (FIG. 1). The implementation depicted in FIG. 3 shows the executions of a pull-up and/or a pull-down test. Both pull-up and pull-down tests should be performed to test a data line 3A-N (FIG. 1) of the input of a tri-state driver 5A-N (FIG. 1). To test an enable line 4A-N (FIG. 1) of a tri-state driver 5A-N (FIG. 1), only one test need be performed.

First, the driver analyzer 40 is initialized and sets the information to be identified at step 41. The information set incorporates the identification of the tri-state bus to be tested, and includes but is not limited to, the specific bus, group of busses, or all the tri-state busses on the chip. At step 42, the driver analyzer 40 establishes the connection to the tri-state bus under test.

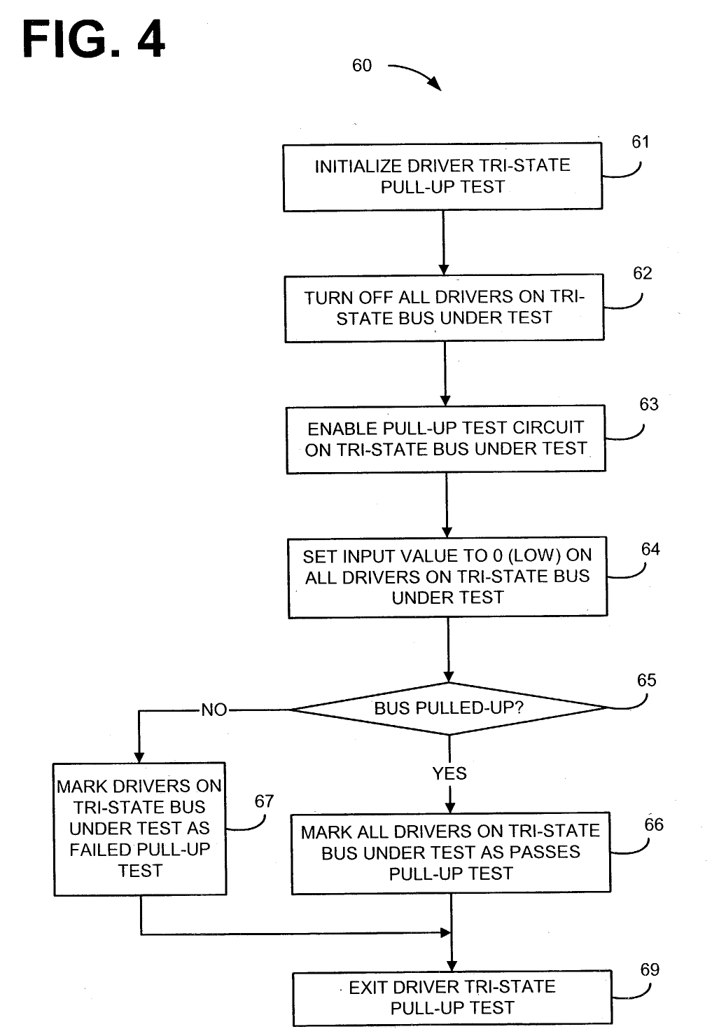

At step 43, the driver analyzer 40 determines if a driver tri-state pull-up test is to be performed. If the driver analyzer 40 determines at step 43 that the driver tri-state pull-up test is not to be performed, the driver analyzer 40 skips to step 51 to perform the driver tri-state pull-down test. However, if it is determined at step 43 that the driver tri-state pull-up test is to be performed, the driver analyzer 40 then performs the driver tri-state pull-up test at step 44. The driver tri-state pull-up test is herein defined in further detail with regard to FIG. 4.

At step 45, the driver analyzer 40 determines if the tri-state bus line remain pulled-up and passed the pull-up test. If it is determined at step 45 that the tri-state bus did not pass the driver tri-state pull-up test, the driver analyzer 40 displays a notice that the tri-state bus circuit failed a driver tri-state test at step 54 and proceeds to step 55. However, if it is determined at step 45 that the tri-state bus passed the driver tri-state pull-up test, then the driver analyzer 40 determines if a driver tri-state pull-down test is to be performed at step 46. If the driver analyzer 40 determines at step 46 that the driver tri-state pull-down test is not to be performed, the driver analyzer 40 skips to step 53 to displays a notice that the tri-state bus circuit passed a driver tri-state test.

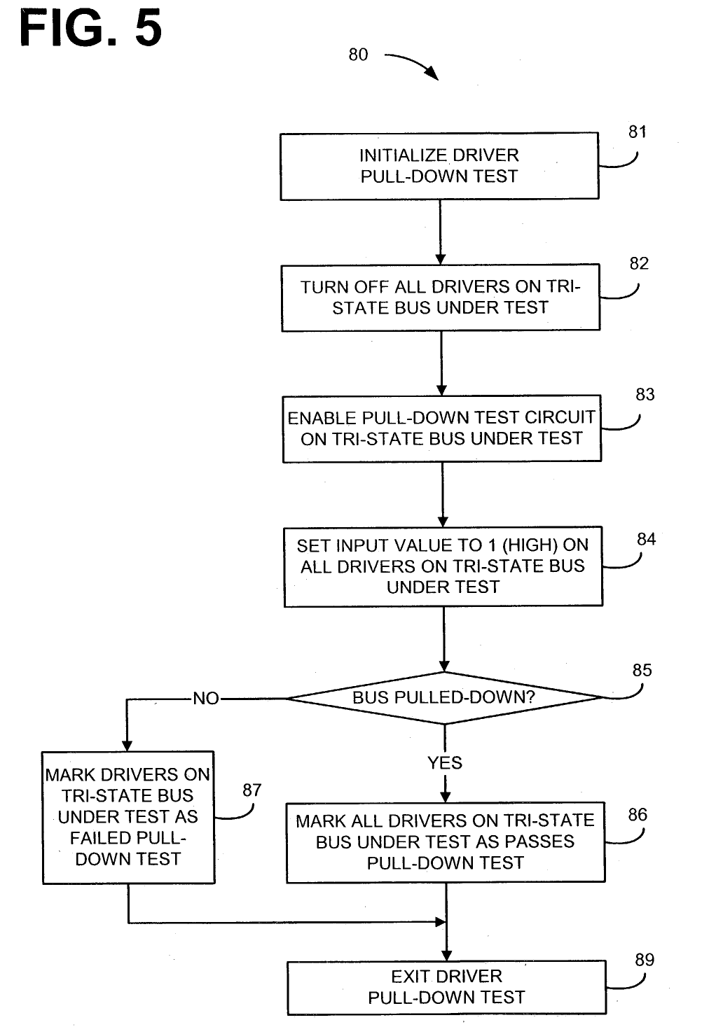

However, if it is determined at step 46 that the driver tri-state pull-down test is to be performed, then the driver analyzer 40 performs the driver tri-state pull-down test at step 51. The driver tri-state pull-down test is herein defined in further detail with regard to FIG. 5. At step 52, the driver analyzer circuitry 10 determines if the tri-state bus remained pulled-down and passed the pull-down test. If it is determined at step 52 that the tri-state bus did pass the driver tri-state pull-down test, the driver analyzer 40 displays a notice that the tri-state bus circuit passed a driver tri-state test at step 53 and skips to step 55. If it is determined at step 52 that the tri-state bus did not pass the driver tri-state pull-down test, the driver analyzer 40 displays a notice that the tri-state bus circuit failed a driver tri-state test at step 54.

At step 55, the driver analyzer 40 determines if there are additional tri-state buses to be tested. If it is determined at step 55 that there are additional tri-state buses to be tested, the driver analyzer 40 proceeds to step 42 to establish a connection to the next tri-state bus to be tested. If it is determined at step 55 that there are no more tri-state buses to be tested, then the driver analyzer 40 exits at step 59.

FIG. 4 is a flow chart illustrating an example of one possible implementation of a method of a driver pull-up test 60 utilized in the driver analyzer 40, as shown in FIGS. 1, 2, and 3. The driver pull-up test 60 performs a test on the tri-state bus 6 (FIG. 1) under test to check stuck-on faults on the enable line 4 (FIG. 1) of a tri-state bus driver 5 (FIG. 1). The testing of the tri-state bus driver 5 on the tri-state bus 6 under test is performed in order to determine if a tri-state bus driver 5 is unsatisfactory. If it is determined that one of the tri-state bus drivers 5 on the pull-up tests fails, then the driver analyzer 40 marks the driver circuitry as unsatisfactory.

First, the driver tri-state pull-up test 60 is initialized at step 61 (FIG. 4). At step 62, the driver tri-state pull-up test 60 turns off all the tri-state bus drivers 5 on the tri-state bus 6 under test. At step 63, the pull-up test circuitry 11 (FIG. 1) is enabled on the tri-state bus 6 under test. The pull-up test circuitry 11 is enabled when pull-up signal 13 (FIG. 1) connects the FET 15 (FIG. 1) to VDD (FIG. 1). Upon connecting the FET 15 to VDD, a high signal is then connected to the tri-state bus 6, thereby pulling the tri-state bus 6 high. At step 64 (FIG. 4), the data input lines 3 (FIG. 1) are then driven low in order to set the initial test state.

At step 65 (FIG. 4), the driver tri-state pull-up test 60 determines if the tri-state bus 6 remained pulled-up. If it is determined in step 65 that the tri-state bus 6 is not pulled-up, the driver tri-state pull-up test 60 marks the tri-state bus drivers 5 on tri-state bus 6 under test as failing the pull-up test at step 66, and the driver tri-state pull-up test 60 exits at step 69. However, if it is determined at step 65 that the tri-state bus 6 is pulled-up, then the driver tri-state pull-up test 60 marks the tri-state bus drivers 5 on the tri-state bus 6 under test as passing the pull-up test at step 66, and then the driver tri-state pull-up test 60 exits at step 69.

FIG. 5 is a flow chart illustrating an example of one possible implementation of a method of a driver pull-down test 80 utilized in the driver analyzer 40, as shown in FIGS. 1, 2, and 3. The driver pull-down test 80 performs a test on the tri-state bus 6 (FIG. 1) under test to check stuck-on faults on the enable line 4 (FIG. 1) of a tri-state bus driver 5 (FIG. 1). The testing of the tri-state bus driver 5 on the tri-state bus 6 under test is performed in order to determine if a tri-state bus driver 5 is unsatisfactory. If it is determined that one of the tri-state bus drivers 5 on the pull-down tests fails, then the driver analyzer 40 marks the driver circuitry as unsatisfactory.

First, the driver tri-state pull-down test 80 is initialized at step 81 (FIG. 4). At step 82, the driver tri-state pull-down test 80 turns off all the tri-state bus drivers 5 on the tri-state bus 6 under test. At step 83, the pull-down test circuitry 12 (FIG. 1) is enabled on the tri-state bus 6 under test. The pull-down test circuitry 12 is enabled when pull-down signal 14 (FIG. 1) connects the FET 16 (FIG. 1) to ground (FIG. 1). Upon connecting the FET 16 to ground, a low signal is then connected to the tri-state bus 6, thereby pulling the tri-state bus 6 low. At step 84 (FIG. 5), the data input lines 3 (FIG. 1) are then driven high in order to set the initial test state.

At step 85 (FIG. 5), the driver tri-state pull-down test 80 determines if the tri-state bus 6 remained pulled-down. If it is determined at step 85 that the tri-state bus 6 is not pulled-down, the driver tri-state pull-down test 80 marks the tri-state bus drivers 5 on tri-state bus 6 under test as failing the pull-down test at step 86, and the driver tri-state pull-down test 80 exits at step 89. However, if it is determined at step 85 that the tri-state bus 6 is pulled down, then the driver tri-state pull-down test 80 marks the tri-state bus drivers 5 on the tri-state bus 6 under test as passing the pull-down test at step 86, and then the driver tri-state pull-down test 80 exits at step 89.

The foregoing description is not intended to be exhaustive or to limit the invention to the precise forms disclosed. Obvious modifications or variations are possible in light of the above teachings. In this regard, the embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly and legally entitled.

What is claimed:

1. A method for testing tri-state bus drivers of a tri-state bus in an integrated circuit comprising:
selecting a tri-state bus to be tested;
performing a tri-state test comprising:
switching off enable signals for all drivers of the tri-state bus;
forcing the tri-state bus to a first value;
setting all driver data inputs to a second value different than the first value; and
determining if the first value remains on the tri-state bus.

2. The method as defined in claim 1, wherein the first value is a logic zero and the second value is a logic one.

3. The method as defined in claim 1, wherein the first value is a logic one and the second value is a logic zero.

4. The method as defined in claim 1, wherein the step of forcing the tri-state bus to a first value further comprises:
activating a FET between the tri-state bus and a logic one.

5. The method as defined in claim 4, wherein the step of activating a FET between the tri-state bus and logic one further comprises:
controlling at least one input of the integrated circuit such that the gate of the FET is turned on.

6. The method as defined in claim 1, wherein the first value is weak.

7. The method as defined in claim 1, wherein the step of forcing the tri-state bus to a first value further comprises:
activating a FET between the tri-state bus and logic zero.

8. The method as defined in claim 7, wherein the step of activating a FET between the tri-state bus and logic zero further comprises:
controlling at least zero input of the integrated circuit such that the gate of the FET is turned on.

9. The method as defined in claim 1, wherein the step of switching off enable signals for all drivers on the tri-state bus further comprises:
controlling at least one input of the integrated circuit such that a disable value is placed on the enable line of each driver.

10. The method as defined in claim 1, wherein the step of determining if the first value remains on the tri-state bus further comprises:
outputting the value on the tri-state bus to a testing device; and
comparing the outputted value to the first value.

11. A system for testing a plurality of tri-state bus drivers of a tri-state bus in an integrated circuit comprising:
means for selecting a tri-state bus to be tested;
means for switching off enable signals for all drivers of the tri-state bus;
means for forcing the tri-state bus to a first value;
means for setting all driver data inputs to a second value different than the first value; and
means for determining if the first value remains on the tri-state bus.

12. The system as defined in claim 11, wherein the first value is a logic zero and the second value is a logic one.

13. The system as defined in claim 11, wherein the first value is a logic one and the second value is a logic zero.

14. The system as defined in claim 11, wherein the first value is weak.

15. The system as defined in claim 11, further comprising:
means for activating a FET between the tri-state bus and a logic one.

16. The system as defined in claim 15, further comprising:
means for controlling at least one input of the integrated circuit such that the gate of the FET is turned on.

17. The system as defined in claim 11, further comprising:
means for activating a FET between the tri-state bus and logic zero.

18. The system as defined in claim 17, further comprising:
means for controlling at least zero input of the integrated circuit such that the gate of the FET is turned on.

19. The system as defined in claim 11, further comprising:
means for controlling at least one input of the integrated circuit such that a disable value is placed on the enable line of each driver.

20. The system as defined in claim 11, further comprising:
means for outputting the value on the tri-state bus to a testing device; and
means for comparing the outputted value to the first value.

21. A system for testing tri-state bus drivers comprising:
a tri-state bus to be tested;
at least one tri-state bus driver connected to the tri-state bus to be tested; and
a switchable pull-up driver test circuitry connected to the tri-state bus to be tested.

22. The system as defined in claim 21, further comprises:
means for causing the at least one tri-state bus driver connected to the tri-state bus to force a first value on the tri-state bus;
means for disabling the at least one tri-state bus driver connected to the tri-state bus; and
wherein the switchable pull-up driver test circuitry forces a second value onto the tri-state bus when a pull-up signal is applied.

23. The system as defined in claim 22, further comprising:
means for determining if the at least one tri-state driver connected to the tri-state bus continues to reflect the second value; and
means for marking the at least one tri-state driver connected to the tri-state bus as good if the tri-state bus reflects the second value.

24. The system as defined in claim 22, wherein the second value is weaker than the first value when the first value is driven by one enabled tri-state driver of the tri-state bus

25. The system as defined in claim 22, further comprising:
means for controlling the pull-up signal.

26. The system as defined in claim 25, wherein the controlling means further comprises:
a storage device.

27. The system as defined in claim 26, where the storage device is a scanable flip-flop.

28. The system as defined in claim 21, further comprising:
means for capturing a value on the tri-state bus.

29. The system as defined in claim 28, where the capturing means further comprises:
a storage device.

30. The system as defined in claim 29, where the storage device is a scanable flip-flop.

31. The system as defined in claim 21, wherein the switchable pull-up driver test circuitry further comprises a transistor.

32. A system for testing tri-state bus drivers comprising:
a tri-state bus to be tested;
at least one tri-state bus driver connected to the tri-state bus to be tested; and
a switchable pull-down driver test circuitry connected to the tri-state bus to be tested.

33. The system as defined in claim 32, further comprising:
means for causing the at least one tri-state bus driver connected to the tri-state bus to force a first value on the tri-state bus;
means for disabling the at least one tri-state bus driver connected to the tri-state bus; and
wherein the switchable pull-down driver test circuitry forces a second value onto the tri-state bus when a pull-down signal is applied.

34. The system as defined in claim 33, further comprising
means for determining if the at least one tri-state driver connected to the tri-state bus continue to reflect the second value; and
means for marking the at least one tri-state driver connected to the tri-state bus as good if the at least one tri-state driver connected to the tri-state bus reflects the second value.

35. The system as defined in claim 33, wherein the second value is weaker than the first value.

36. The system as defined in claim 33, further comprising:
means for controlling the pull-down signal.

37. The system as defined in claim 33, wherein the controlling means further comprises:
a storage device.

38. The system as defined in claim 37, where the storage device is a scanable flip-flop.

39. The system as defined in claim 32, further comprising:
means for capturing a value on the tri-state bus.

40. The system as defined in claim 39, where the capturing means further comprises:
a storage device.

41. The system as defined in claim 40, where the storage device is a scanable flip-flop.

42. The system as defined in claim 32, wherein the pull-down driver test circuitry further comprises a transistor.
